(19) United States
(12) Patent Application Publication
(10) Pub. No.: US 2018/0101099 A1
(43) Pub. Date: Apr. 12, 2018

(54) Lithographic Apparatus

(71) Applicant: ASML Netherlands B.V., Veldhoven (NL)

(72) Inventors: Günes NAKIBOGLU, Eindhoven (NL); Marc Wilhelmus Maria VAN DER WIJST, Veldhoven (NL); Martinus VAN DUIJNHOVEN, Deurne (NL); Cornelius Adrianus Lambertus DE HOON, Eindhoven (NL); Frank Johannes Jacobus VAN BOXTEL, Eindhoven (NL)

(73) Assignee: ASML Netherlands B.V., Veldhoven (NL)

(21) Appl. No.: 15/567,103

(22) PCT Filed: Mar. 8, 2016
(86) PCT No.: PCT/EP2016/054883

§ 371 Date: Oct. 17, 2017

(30) Foreign Application Priority Data
Apr. 17, 2015 (EP) 15164042.2
Jun. 5, 2015 (EP) 15170896.3

(51) Int. Cl. G03F 7/20

(52) U.S. Cl. CPC G03F 7/20; G03F 7/709

(57) ABSTRACT

A lithographic apparatus has shield which protects a functional subsystem form acoustic disturbances. The shield comprises a locally resonant sonic material for implementing the protecting. In an embodiment the shield comprises a panel formed by a cell or a plurality of cells comprising: a frame; an elastic membrane whose edge is fixed to the frame; and a mass attached to a location at the membrane at a non-zero distance from the edge.

### CROSS-REFERENCE TO RELATED APPLICATIONS

This application claims priority of EP applications 15164042.2 and 15170896.3 which were filed on 17 Apr. 2015 and 5 Jun. 2015 and which are incorporated herein in its entirety by reference.

### BACKGROUND

### Field of the Invention

The present invention relates to a lithographic apparatus.

### Description of the Related Art

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

An object in a lithographic apparatus, for example a substrate table or a support structure for a patterning device, that moves in a gaseous environment can create an acoustic disturbance, so-called acoustic pressure waves, e.g. acoustic noise. An acoustic disturbance within the apparatus can cause disturbing forces that result in errors in the positioning of objects such as the substrate or the patterning device, which can in turn lead to overlay errors. Such positioning errors can be caused by the acoustic disturbance acting directly on the object being positioned or indirectly, e.g. by the acoustic disturbance affecting measuring systems such as grid-encoder based or interferometer positioning systems or alignment sensors.

US 2012/0242271 A1 discloses an approach to minimizing the effect of noise on the positioning of an object table by sensing the noise and taking account of the sensed noise in control of the position of the object. It is also suggested that passive dampers such as Helmholtz resonators can be placed adjacent to the projection system to dampen vibrations at specific frequencies. However, these approaches do not address all acoustic disturbances that can occur.

### SUMMARY

It is desirable to provide an alternative approach to the mitigation of vibrations in a lithographic apparatus.

According to an aspect of the invention, there is provided a lithographic apparatus configured for imaging a pattern onto a substrate. The lithographic apparatus comprises a system, which is exposed to a gas and whose operation is sensitive to an acoustic disturbance in the gas. The lithographic apparatus further comprises a shield for protecting the system against the acoustic disturbance. The shield comprises an acoustic metamaterial having a sonic band gap in a frequency range of the acoustic disturbance.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus;

FIG. 2 depicts a panel forming a shield of an embodiment of the invention;

FIG. 3 depicts a cell of the panel of FIG. 2;

FIG. 4 depicts acoustic transmission as a function of frequency for a shield according to an embodiment of the invention;

FIG. 5 depicts a shield of an embodiment of the invention formed by a plurality of panels;

FIG. 6 depicts sound transmission loss in dB as a function of frequency for several different shields of embodiments of the invention;

FIG. 7 depicts a shield of an embodiment of the invention formed by a plurality of panels;

FIG. 8 depicts a panel forming a shield of an embodiment of the invention;

FIG. 9 depicts a panel forming a shield of an embodiment of the invention;

FIG. 10 depicts a panel forming a shield of an embodiment of the invention;

FIG. 11 depicts a shield of an embodiment of the invention protecting a projection system;

FIG. 12 depicts a shield of an embodiment of the invention protecting a projection system; and

FIG. 13 depicts a shield of an embodiment of the invention protecting an alignment system.

### DETAILED DESCRIPTION

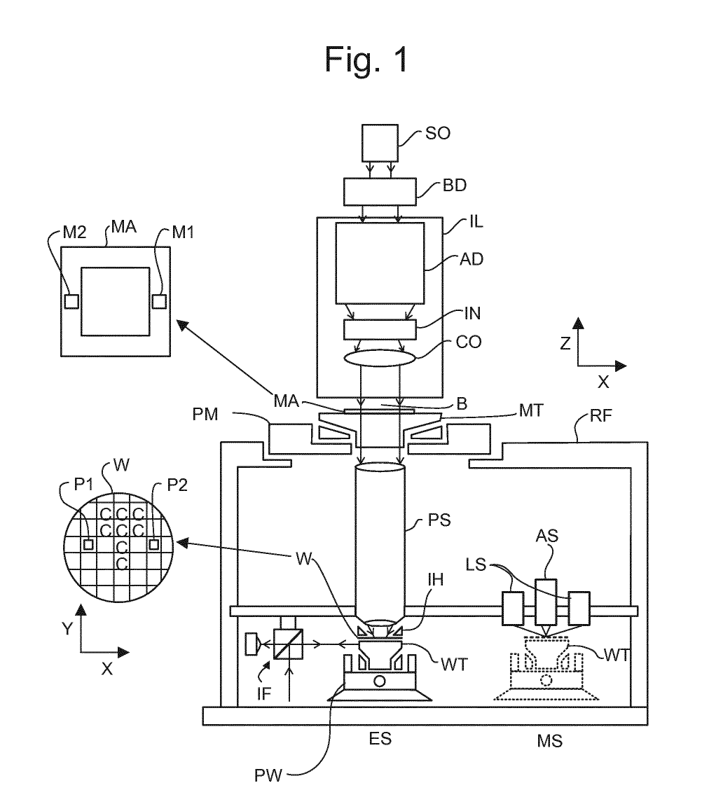

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning device PM configured to accurately position the patterning device in accordance with certain parameters. The apparatus also includes a substrate table (e.g. a wafer table) WT or “substrate support” constructed to hold a substrate (e.g. a resist-coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. It holds the patterning device in a manner that depends on the orientation of the patterning device, the design of the lithographic apparatus, and other conditions. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, magnetic, electromagnetic and electrostatic optical systems, or any combination thereof, as appropriate for the exposure radiation being used, or for other factors such as the use of an immersion liquid. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B.

Similarly, the first positioning device PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW.

In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

In a lithographic apparatus it is desirable to achieve a high through-put, i.e. a large number of substrates exposed per hour. To achieve a high through-put, the wafer tables and mask support structure are moved at high velocities and high accelerations. Other components of the apparatus may also be moved rapidly. These moving objects cause acoustic disturbances, e.g. noise. A lithographic apparatus also includes various moving fluids, for example: a thermal transfer liquid (e.g. water) used to thermally condition various parts of the lithographic apparatus, an immersion liquid through which the substrate is exposed and a purge gas (e.g. nitrogen or pressurized and/or filtered or purified air) used to ensure a consistent environment for optical beams and temperature conditioning. The movement of these fluids as well as the pumps or fans driving these fluids may also generate acoustic disturbances. There may be other or additional sources of acoustic disturbances in the lithographic apparatus.

Several systems of the lithographic apparatus may suffer deleterious effects from acoustic disturbances, for example the projection system PS and measurement systems such as the alignment sensor AS and level sensor LS. The deleterious effects may include imaging errors, e.g. overlay errors, caused directly by displacement of the functional system by the acoustic disturbances or indirectly by measurement errors induced by the acoustic disturbances.

The lithographic apparatus is designed so that the acoustic disturbances generated by each of the many sources are minimized. However, acoustic disturbances may still be present with significant amplitudes in the relevant frequency ranges to which the operation of the various systems of the lithographic apparatus is sensitive. Whilst prior approaches to the problem of acoustic disturbances have concentrated on minimizing the generation of acoustic disturbances and/or improving the damping of acoustic disturbances, the present inventors propose a different approach.

In an embodiment of the invention, it is proposed to provide a shield to protect a system from an acoustic disturbance, wherein the shield comprises an acoustic metamaterial having a sonic band gap in a frequency range of the acoustic disturbance.

As known, an acoustic metamaterial is an artificially fabricated material that is designed to control sound waves (or: acoustic waves) as occurring in an elastic medium such as a gas. Metamaterials gain their properties from their spatial structure rather than from their composition. A metamaterial can be tuned to have a dip in the spectrum of the transmission of sound at a specific frequency range. The dip is also referred to as a “sonic band gap”. Various types of acoustic metamaterials exist.

One type is referred to in the literature as a “phononic crystal”, whose operation is based on the scattering of sound waves inside heterogeneous periodic materials.

Another type of metamaterial is referred to in the literature as “locally resonant sonic material”, that is formed by an assembly of soft bodies and rigid bodies whose combined operation is based on resonant phenomena.

For more general background on acoustic metamaterials, please see, e.g., —“Acoustic Metamaterials and Phononic Crystals”, Jun Mei et al., Springer Series in Solid-State Sciences, Volume 173, 2013, Chapter 5, pp 159-199; —“Acoustic metamaterial panels for sound attenuation in the 50-1000 Hz regime”, Z. Yang et al., Appl. Phys. Lett 96, 041906 (2010); —“Membrane-Type Acoustic Metamaterial with Negative Dynamic Mass”, Z. Yang et al., Phys. Rev. Lett. 101, 204301 (2008); —“Comparison of the sound attenuation efficiency of locally resonant materials and elastic band-gap structures”, Cécile Goffaux et al., Phys. Rev. B 70 184302 (2004); —“Modelling and Experimental Validation of Complex Locally Resonant Structures”, Andrew J. Hall et al., New Zealand Acoustics Vol. 24/#2, pp 12-23.

In an embodiment of the invention, the acoustic metamaterial comprises a locally resonant sonic material. The present inventors have determined that the approach of protecting the systems that are most sensitive to acoustic disturbances is more effective and more efficient than further reducing the generation of acoustic disturbances because the number of sources is larger than the number of sensitive systems and the contributions from each source are similar. Also, the systems have different frequency dependencies and so the shield of an embodiment can be configured to shield a system from acoustic disturbances of one or more frequencies or frequency ranges to which the system is most sensitive.

An advantage of implementing the shield with locally resonant sonic material is that a (much) smaller volume is required for accommodating the shield than is needed for a shield implemented with, e.g., a phononic crystal, in order to protect the system against acoustic disturbances in the relevant frequency range between 50 Hz and 1500 Hz, or between 300 Hz and 1000 Hz. Space is available in a lithographic apparatus at a premium, if at all. Therefore, the use of locally resonant material for neutralizing the impact of these low-frequency acoustic disturbances has great advantages in a lithographic apparatus.

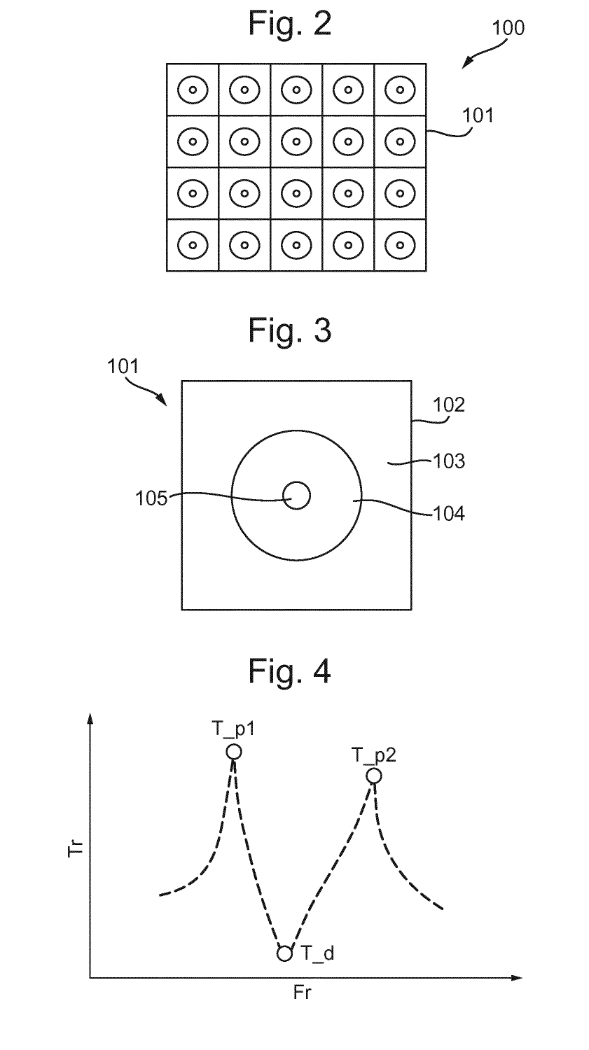

FIG. 2 depicts schematically a panel 100 which can be employed as shield in an embodiment of the invention. Panel 100 comprises a plurality of cells 101, one of which is depicted enlarged in FIG. 3.

Cell 101 comprises a frame 102 and a plate 103 having an aperture in which is fixed an elastic membrane 104. In the example shown, a (lumped) mass 105 is attached to the center of membrane 104. Frame 102, 103 is desirably rigid whilst membrane 104 is free to vibrate under the influence of acoustic disturbances impinging upon it. The acoustic transmission (‘Tr’) of the cell 101 is depicted in FIG. 4 as function of the frequency (‘Fr’).

It will be seen that the acoustic transmission of the cell 101 has two peaks T_p1 and T_p2. The first peak T_p1 corresponds to an eigenmode in which the membrane and mass vibrate in unison, whereas the second peak T_p2 corresponds to an eigenmode in which the membrane vibrates but the mass remains motionless. In between T_p1 and T_p2 there is a frequency at which the in-plane average displacement (normal to the membrane rest position) is substantially zero, leading to a minimum transmission T_d at frequency f(T_d). At the transmission minimum, the cell acts like a nodal point in wave propagation and the acoustic energy is reflected, rather than absorbed. Thus, by placing the shield between a source of acoustic disturbances and a functional system that is sensitive to acoustic disturbances at or near f(T_d), the functional system can be protected.

The acoustic properties of the cell and in particular the frequency f(T_d) of the transmission minimum are dependent on the mechanical properties of the assembly making up the cell. Parameters of the cell design that can be selected to determine its acoustic properties include: a size of the membrane 104, a shape of the membrane 104, a density (kg/m²) of the membrane 104, an elasticity (Young's modulus) of the membrane 104, a tension of the membrane 104, a thickness of the membrane 104, an inertial mass (in kilograms) of the (lumped) mass 105, a position of the mass 105 relative to the membrane 104, and a number of masses attached to the membrane 104. In addition, one could affect the acoustic properties of the cell via a non-uniformity of the membrane 104. For example, the density and/or thickness of the membrane 104 need not be uniform across the membrane.

Appropriate properties to achieve a desired value of f(T_d) can be calculated and verified by measurement and/or simulation.

In particular, it is noted that the frequency of the first transmission peak f(T_p1) depends strongly on the inertial mass of the mass 105 whereas the frequency of the second transmission peak f(T_p2) does not. Therefore, the frequency f(T_d) of the transmission minimum can be shifted towards lower frequencies by increasing the inertial mass of the mass 105. Therefore, the shield can be configured to have maximum sound reflectance at a frequency to which the system is sensitive.

The properties of the frame 102, 103 do not particularly affect the acoustic properties of the shield as long as the frame 102, 103 is sufficiently rigid. The frame 102 can conveniently be made of a grid of bars 102 and plates 103, with each plate having an aperture defining the shape of the membrane. Frame 102 and plates 103 can be made of a metal, such as aluminum, plastics or other suitable rigid materials. The membrane can be made of any suitable impermeable material such as. The mass can be made of any dense material such as lead or alloys thereof.

The membrane may be attached to the frame by an adhesive, by welding or by a mechanical clamp. Tension in the membrane can be controlled by pre-tensioning the membrane prior to attachment or by a tensioning device after attachment to the frame. The mass may be attached to the membrane by an adhesive, by welding or by a mechanical clamp.

The dimensions of the cell may be of order 5 mm to 500 mm. The diameter of the membrane may be between 5 mm and 500 mm. The mass 105 may have an inertial mass of from about 0.1 g to 50 g.

The panel may have a plurality of cells, e.g. from 2 to 1000 or more. The size of the panel is selected according to the size of the system to be protected and/or the locations of the source of acoustic disturbance.

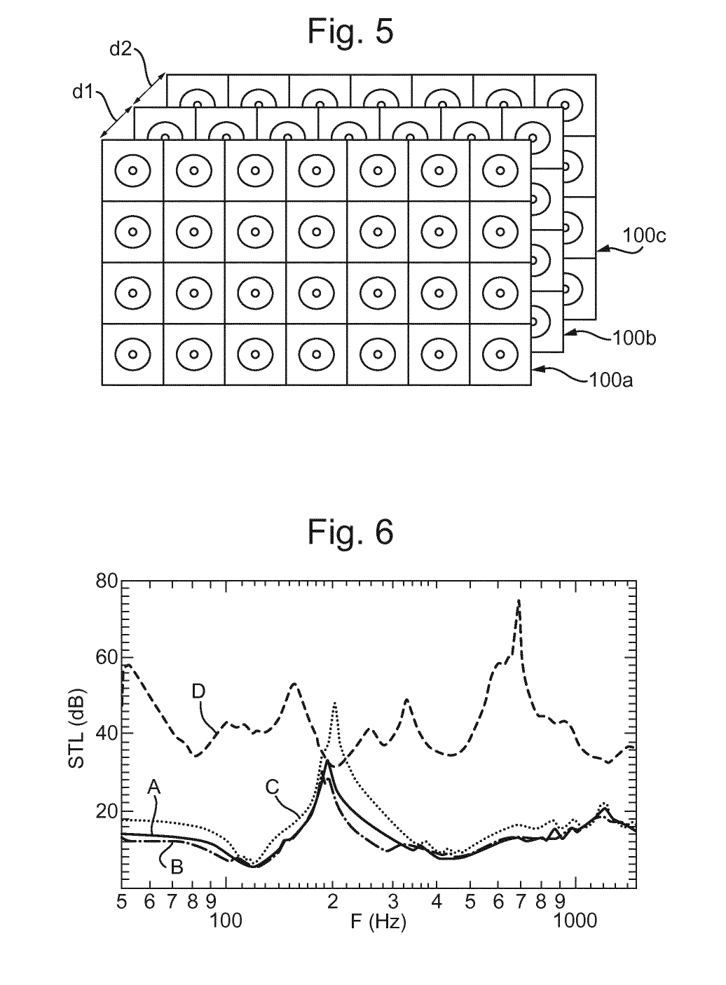

FIG. 5 depicts a shield according to another embodiment of the invention. The shield of FIG. 5 comprises a plurality of panels 100a, 100b, 100c arranged in a cascade between the source of acoustic disturbance and the system to be protected. As depicted there are three cascaded panels however there may be any practical number of panels from two to, e.g., ten. The spacings d1, d2 between the panels are sufficient that an evanescent wave generated by the vibration of one panel does substantially not reach the next panel, i.e. the distance between adjacent panels is greater than the extent of the evanescent wave. Therefore the panels function independently of one another. The spacing between panels may be greater than about 10 mm. The functioning of the panels does not place an upper limit on their spacing but to minimize the space taken up by the shield the panels are desirably as close together as possible.

As known, an evanescent wave is a near-field wave with an intensity that decays exponentially with distance from the boundary at which the wave was formed. The evanescent wave exists as a result of the fact that the magnitude of the pressure of the acoustic wave cannot be discontinuous across a boundary between two media. If the pressure were discontinuous, acceleration of the material through which the acoustic wave is propagating, would be infinite as the acceleration is proportional to the pressure gradient in the mathematical models being used.

As described above, the spacing between subsequent panels in a cascade of panels is greater than the extent of the evanescent wave. The decay of the evanescent wave is exponential with distance from the boundary, i.e., from the panel in a direction substantially perpendicular to the panel. The extent of the evanescent wave can be quantified in various manners. The extent could be taken as the length of the distance over which the intensity of the evanescent wave has dropped below a threshold magnitude, beneath which the evanescent wave does not have a substantial effect anymore when it comes to the shielding of the system. Alternatively, the extent could be taken as the length of distance over which the intensity has dropped to an acceptable magnitude, e.g., at that distance the evanescent wave cannot be distinguished anymore from the intensity of (random) thermal movement of the molecules of the gaseous medium between the panels.

In an embodiment, the separate panels of a shield having a plurality of panels mounted in cascade are configured to have different acoustic properties, in particular different frequencies of minimum transmission f(T_d). The effect of this is shown in FIG. 6. In FIG. 6, which is a graph of measured sound transmission loss (dB) as a function of frequency (Hz), the different lines indicate:
A (solid black line)—a first single layer panel
B (dot-chain line)—a second single layer panel of identical nominal dimensions as the first single layer panel
C (dotted line)—the first and second single layer panels arranged in cascade
D (dashed line)—a four layer shield with four non-identical panels in cascade

It can be seen that the two nominally identical panels have almost identical sound transmission functions having a single peak in sound transmission loss at about 200 Hz. Placing two identical panels in cascade provides a similar shape of sound transmission but with a higher sound transmission loss at a single frequency, in this case slightly shifted from the peak of the two individual panels. However, the multi-layer shield made up of different panels exhibits a very different sound transmission loss as a function of frequency with multiple peaks and a much higher base level of loss (about 30 to 40 dB) between the peaks. This is because the losses caused by each panel are cumulative. The addition of further panels can be expected to further reduce transmission.

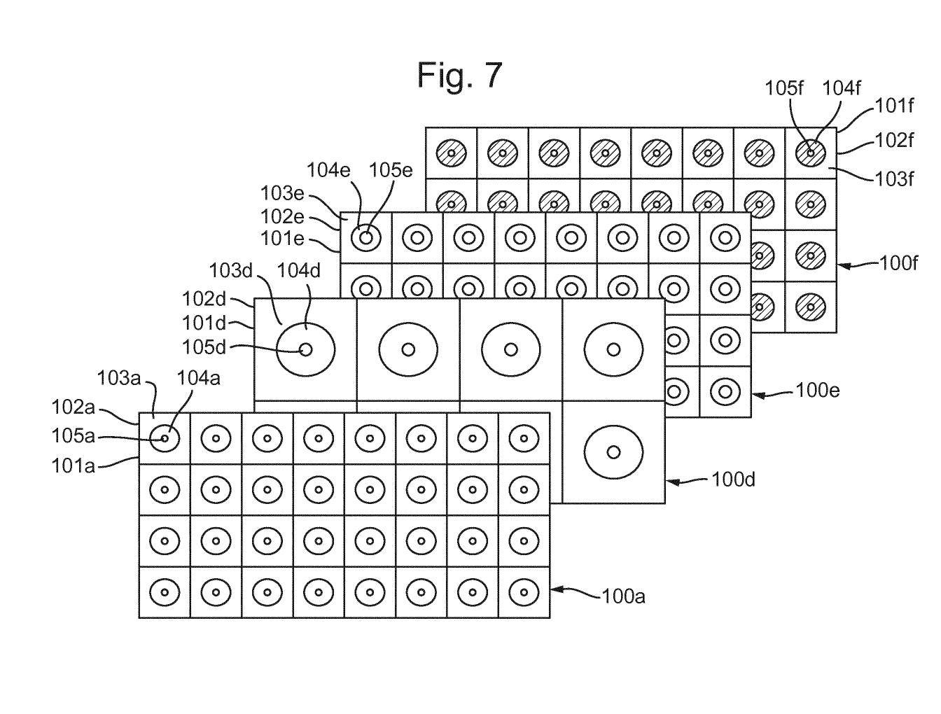

The acoustic properties, and hence the frequencies of minimum transmission, of the panels are varied by varying one or more of the parameters mentioned above. This is depicted in FIG. 7, which illustrates a shield having four different panels 100a, 100d, 100e and 100f. Each panel comprises a plurality of cells 101x each comprising frame 102x, 103x, membrane 104x and mass 105x, where x is the suffix of the panel, e.g. a, d, e, f, etc. . . . This reference scheme is also used in other drawings.

Relative to first panel 100a, second panel 100d has cells 101d of a different size, e.g. twice as big. All other things being equal, increasing the cell size will reduce the frequency of minimum transmission. Relative to first panel 100a, third panel 100e has masses 105e of different mass, e.g. higher. All other things being equal, increasing the mass will reduce the frequency of minimum transmission. Relative to first panel 100a, fourth panel 100f has a membrane 104f with a different modulus of elasticity, e.g. stiffer. All other things being equal, increasing the membrane stiffness will increase the frequency of minimum transmission.

Other parameters of the panels may be varied to change the resonant behavior and hence the frequency of minimum transmission. A panel can be configured to have more than one transmission minimum. It is not necessary that all of the cells of a panel have the same dimensions and properties; different cells can be combined in a single panel.

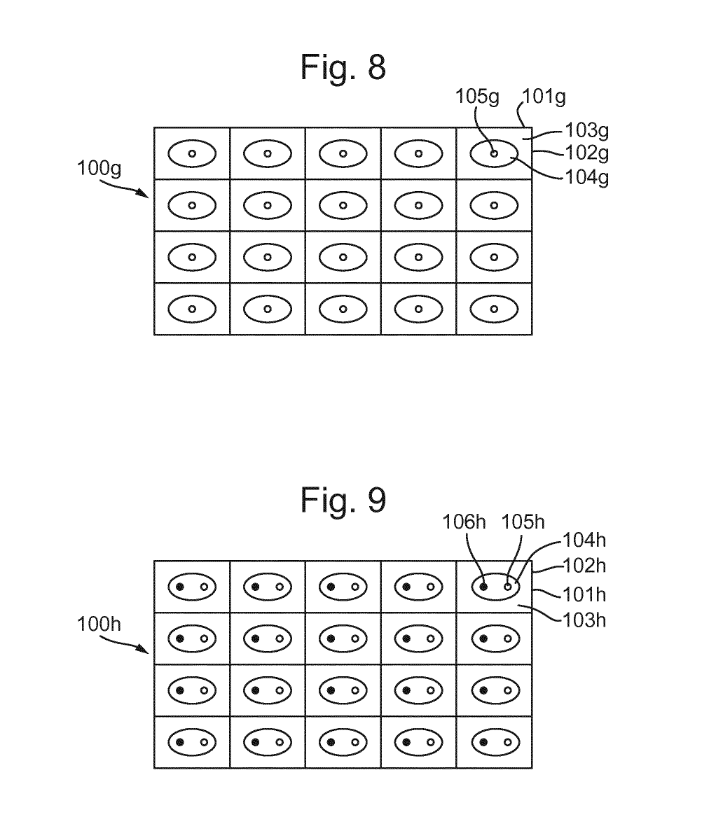

FIG. 8 depicts a panel 100g having rectangular cells 101g and elliptical membranes 104g. Such a panel may have multiple resonances related to the major and minor diameters of the ellipse and hence multiple transmission minima. FIG. 9 depicts a panel 100h similar to panel 100g but with two masses 105h, 106h per cell. This panel may have a complex resonant behavior with modes involving in-phase and out-of-phase movements of the masses 105h, 106h and consequently multiple transmission modes. Multiple masses per cell can be employed with membranes of other shapes than ellipses. In case a panel with multiple masses or a complex membrane shape cannot be accurately modelled, its sound transmission characteristics can be determined by measurement.

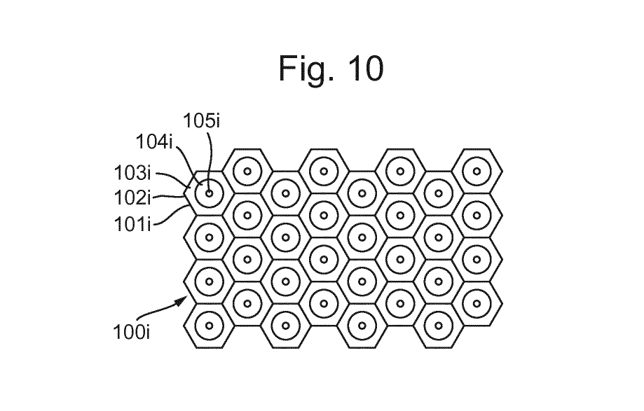

Different shapes of cell can be used in embodiments of the invention. FIG. 10 depicts a panel 100i with hexagonal cells 101i. Cell shapes that tessellate—e.g. triangles, squares, rectangles, parallelograms, rhombuses, hexagons—are convenient but non-tessellating cells can also be used. An arrangement with two or more different mutually tessellating shapes—e.g. squares and octagons—is possible.

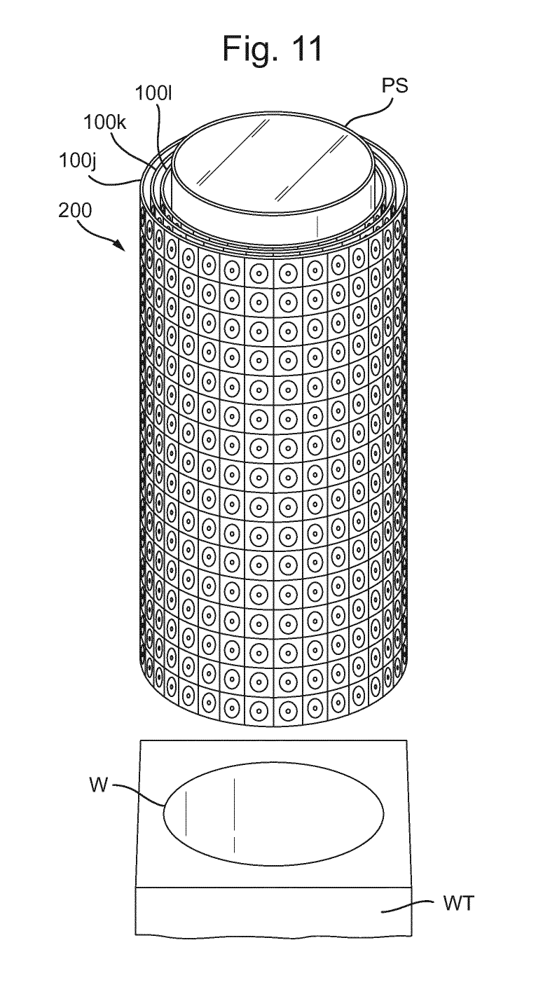

In an embodiment of the invention, the panels are not flat but are shaped to encompass the system as closely as possible. An example is shown in FIG. 11. FIG. 11 depicts a shield 200 that is cylindrical in shape and closely surrounds the projection system PS, as an example of a system. Shield 200 comprises a plurality, in this case three, concentric cylindrical panels 100j, 100k, 100l, having different acoustic properties. Strict concentric arrangement of the panels is not necessary but may be convenient to minimize the overall volume of the shield 200. One or more of the panels 100j, k, l may be cut away to accommodate adjacent components, mounts and utility connections for the projection system or non-cylindrical parts of the projection system PS.

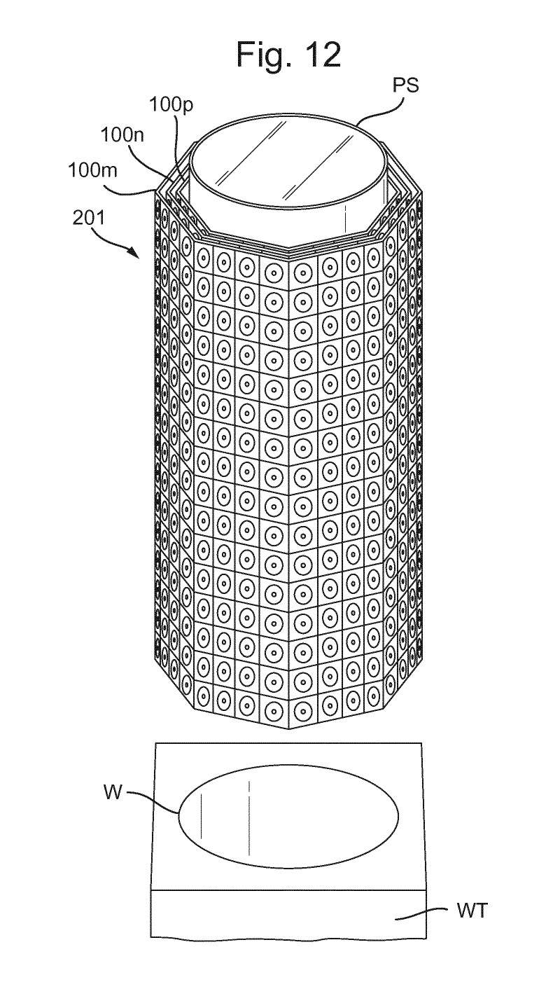

In an embodiment of the invention a shield to enclose a system is made up of a plurality of flat panels. A first example of this is shown in FIG. 12 which depicts shield 201. Shield 201 has a plurality of concentric prisms 100m, n, p, e.g. three, each made up of flat panels arranged and connected edge-to-edge in a polygonal, e.g. octagonal, arrangement. Shield 201 has a greater volume than shield 200 to enclose a system of the same size but can be easier to manufacture.

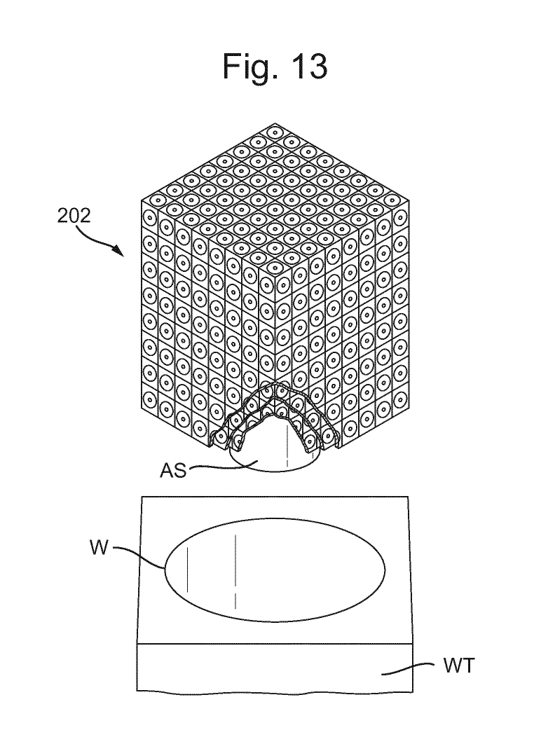

FIG. 13 depicts a shield 202 formed of a plurality of nested boxes (cuboids) open at one end. Shield 202 is suitable to enclose a system, such as alignment sensor AS, which requires only one area for input and output. For an optical sensor, the shield may completely enclose the sensor save for a minimum-sized window to allow entrance and/or exit of measurement radiation.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or more processed layers.

Although specific reference may have been made above to the use of embodiments of the invention in the context of optical lithography, it will be appreciated that the invention may be used in other applications, for example imprint lithography, and where the context allows, is not limited to optical lithography. In a lithographic apparatus that employs very short wavelength radiation to expose substrates, parts of the lithographic apparatus traversed by the radiation beam, e.g. the substrate stage compartment, may be filled with a low pressure of gas, e.g. hydrogen or helium, so as to minimize absorption of the very short wavelength radiation. The low pressure may be referred to as a “vacuum” environment but the present invention is applicable if the gas pressure in a part of the lithographic apparatus is sufficient to transmit acoustic disturbances.

The descriptions above are intended to be illustrative, not limiting. Thus, it will be apparent to one skilled in the art that modifications may be made to the invention as described without departing from the scope of the claims set out below.

1-14. (canceled)

15. A lithographic apparatus configured to image a pattern onto a substrate, wherein:
the apparatus comprises:
a system that is exposed to a gas and is configured to perform an operation that is sensitive to an acoustic disturbance in the gas; and
a shield for protecting the system against the acoustic disturbance, wherein the shield comprises an acoustic metamaterial having a sonic band gap in a frequency range of the acoustic disturbance.

16. The lithographic apparatus of claim 15, wherein the sonic band gap occurs in a frequency range between 50 Hz and 1500 Hz, or between 300 Hz-1000 Hz.

17. The lithographic apparatus of claim 15, wherein the acoustic metamaterial comprises a locally resonant sonic material.

18. The lithographic apparatus of claim 17, wherein the locally resonant sonic material comprises a panel that includes one or more cells, each specific one of the one or more cells comprising:
a frame;
a membrane whose edge is fixed to the frame; and
a mass attached to the membrane at a location at non-zero distance from the edge.

19. The lithographic apparatus of claim 18, wherein the locally resonant sonic material further comprises a second, panel, different from the panel and including one or more second cells, each particular one of the one or more second cells comprising:
a second frame;
a second membrane whose second edge is fixed to the second frame; and
a second mass attached to the second membrane at a second location at a second non-zero distance from the second edge.

20. The lithographic apparatus of claim 19, wherein the second panel is positioned between the panel and the system.

21. The lithographic apparatus of claim 20, wherein the second panel is spaced apart from the panel by a distance greater than the extent of an evanescent wave.

22. The lithographic apparatus of claim 20, wherein the second panel is spaced apart from the panel by a distance greater than about 10 mm.

23. The lithographic apparatus of claim 19, wherein the second cell has a different resonant frequency than the cell.

24. The lithographic apparatus of claim 23, wherein the shield has at least one of following attributes:
the membrane and the second membrane have different sizes;
the membrane and the second membrane have different shapes;
the membrane and the second membrane have different density;
the membrane and the second membrane have different elasticity;
the membrane and the second membrane have different tension;
the membrane and the second membrane have different thickness,
the mass and the second mass have different magnitude; and
the location relative to the edge and the second location relative to the second edge are different.

25. The lithographic apparatus of claim 23, wherein:
the cell has at least one further mass attached to the membrane at a further location at non-zero further distance from the edge.

26. The lithographic apparatus of claim 23, wherein:
the second cell has at least one further second mass attached to the second membrane at a further second location at non-zero further second distance from the second edge.

27. The lithographic, apparatus of claim 15, wherein the system is the optical system.

28. The lithographic apparatus of claim 15, wherein the system is an alignment system.
